(19) United States
(12) Patent Application Publication
(10) Pub. No.: US 2026/0033378 A1
(43) Pub. Date: Jan. 29, 2026

(54) STACKED DIE SUBSTRATE-LESS SEMICONDUCTOR PACKAGE

(71) Applicant: Micron Technology, Inc., Boise, ID (US)

(72) Inventors: Gokul KUMAR, Dublin, CA (US); Hem P. TAKIAR, Fremont, CA (US)

(21) Appl. No.: 19/220,633

(22) Filed: May 28, 2025

Related U.S. Application Data
(60) Provisional application No. 63/674,607, filed on Jul. 23, 2024.

(51) Int. Cl. H01L 23/00; H01L 23/31; H01L 25/07

(52) U.S. Cl. CPC H01L 24/24; H01L 23/3107; H01L 24/19; H01L 25/074; H01L 2224/19; H01L 2224/244; H01L 2225/06562

(57) ABSTRACT

Implementations described herein relate to various semiconductor device assemblies. In some implementations, an apparatus includes a first integrated circuit die conjoined with a second integrated circuit die in a stack of integrated circuit dies, where the first integrated circuit die includes an end region that extends beyond an edge of the second integrated circuit die. The apparatus includes an interconnect structure that is conjoined with the end region and is electrically coupled to integrated circuitry of the first integrated circuit die and a casing that encapsulates at least a portion of the interconnect structure, at least a portion of the first integrated circuit die, and at least a portion of the second integrated circuit die. The apparatus includes an electrical trace that is conjoined with a surface of the casing, is disposed along a contour of the casing, and is electrically coupled to the interconnect structure.

### CROSS-REFERENCE TO RELATED APPLICATION

This Patent application claims priority to U.S. Provisional Patent Application No. 63/674,607, filed on Jul. 23, 2024, entitled “STACKED DIE SUBSTRATE-LESS SEMICONDUCTOR PACKAGE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a stacked die substrate-less semiconductor package.

### BACKGROUND

A semiconductor package may include one or more semiconductor electronic components and a casing to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a flowchart of an example method of forming an integrated assembly or memory device having a stacked die substrate-less semiconductor package.

FIG. 4 is a flowchart of an example method of forming an integrated assembly or memory device having a stacked die substrate-less semiconductor package.

FIG. 5 is a flowchart of an example method of forming an integrated assembly or memory device having a stacked die substrate-less semiconductor package.

FIGS. 6A through 6I are diagrammatic views showing formation of an example apparatus at example process stages of an example process of forming the apparatus.

FIG. 7 is a diagram of an example circuit layout of a redistribution circuit described herein.

FIG. 8 is a diagram of an example implementation described herein.

FIG. 9 is a diagram of an example implementation described herein.

FIG. 10 is a diagram of an example implementation described herein.

### DETAILED DESCRIPTION

In the realm of semiconductor packaging technology, particularly for high-capacity, high-performance applications, manufacturing techniques have relied heavily on through-silicon vias (TSVs) and wire bonding techniques for creating stacked die packages. These existing approaches, while viable, present significant challenges, including increased complexity and costs associated with the preparation of dies, as well as structural issues such as limited ability for thermal management and signal speed degradation due to longer interconnect lengths.

Furthermore, the stacking processes utilizing TSVs and wire bonding impose distinct limitations on testing methodologies. For instance, testing stacked dies becomes increasingly difficult once the connection has been established through TSVs or wire bonds. Moreover, alterations tailored to accommodate specific treatments of the dies, such as thermal management, often require substantial redesign efforts due to the fundamental constraints of the substrate in conventional packages.

To add to the challenges, as the electronics industry demands greater integration, the existing stacking strategies are encumbered by their inflexibility to scale, ultimately impeding the progression toward more compact and efficient system designs. The need for a more adaptable and cost-effective stacking approach persists, one that ensures the integrity of both the dies and their inter-package connections, permits comprehensive testing prior to final assembly, and supports an accelerated and streamlined manufacturing process.

Some implementations described herein involve techniques for constructing stacked die substrate-less semiconductor packages that are designed to optimize the efficiency and performance for high-capacity, high-performance applications. For example, a stacked die substrate-less semiconductor package may include a stack of integrated circuit dies arranged in a shingled fashion with an overhanging region that enables the formation of a stepped profile along the end of the stack, which facilitates efficient space utilization for interconnect structures such as pillar structures or ball bond structures. This structural configuration, along with the encapsulating casing that partially covers the stack, also permits the establishment of a redistribution circuit that conforms to the surface of the casing to effectively connect with the interconnect structures.

The redistribution circuit creates communication pathways by connecting with the interconnect structures, forming robust internal and external channels for intra-package and inter-package signal transmission. This, in turn, allows for stacking of multiple stacked die substrate-less semiconductor packages, resulting in a vertically compact system architecture that inherently offers enhanced thermal dissipation due to minimized thermal resistance pathways and direct contact between the integrated circuitry and heat dissipation elements.

In this way, the stacked die substrate-less semiconductor package is advanced over conventional TSV and wire bonding stacking methods by offering a more efficient and scalable approach for die stacking. The substrate-less construction improves thermal conductance and reduces signal transit distances, thereby enhancing signal integrity and thermal management within the device. By improving the quality and/or the reliability of the stacked-die substrate-less semiconductor package, an amount of resources used to support a market consuming the semiconductor device (e.g., raw materials, semiconductor manufacturing tools, labor, and/or computing resources) is reduced. Furthermore, the design permits the completion of comprehensive electrical testing before final assembly, supports adaptable scaling for various package configurations with minimal design changes, and streamlines the manufacturing process, thereby promoting resource conservation in the production of semiconductor devices.

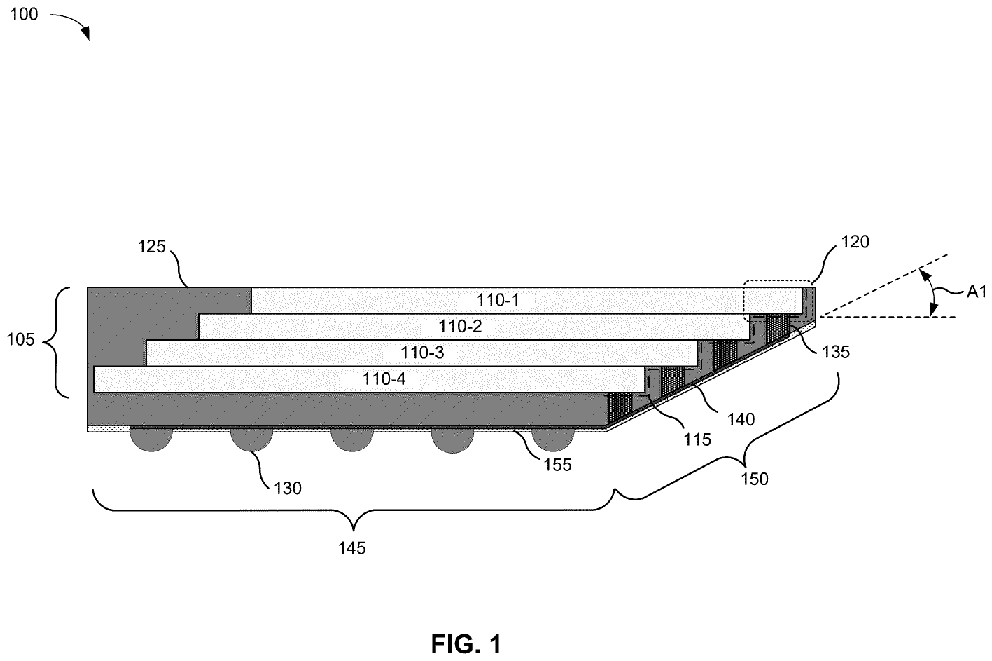

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include an integrated circuit 105. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). Although the apparatus 100 is shown as including a single integrated circuit 105 as an example, the apparatus 100 may include a different number of integrated circuits 105.

In some implementations, an integrated circuit 105 may include multiple semiconductor dies 110 (sometimes called dies), which is shown as including four semiconductor dies 110-1 through 110-4. As shown in FIG. 1, for an integrated circuit 105 that includes multiple dies 110, the dies 110 may be stacked on top of each other to reduce a footprint of the apparatus 100. Although the integrated circuit 105 is shown as including four dies 110, an integrated circuit 105 may include a different number of dies 110.

In some implementations, and as shown in FIG. 1, the dies 110 are stacked in a shingled fashion that causes a stepped profile 115. The stepped profile 115 may result in one or more of the dies 110 having an end region 120 that extends beyond an edge of an underlying die (e.g., as shown in FIG. 1, the end region 120 of the die 110-1 extends beyond an edge of the die 110-2 and overhangs the die 110-2).

The apparatus 100 may include a casing 125 that protects internal components of the apparatus 100 (e.g., the integrated circuit 105) from damage and environmental elements (e.g., particles) that can lead to malfunction of the apparatus 100. The casing 125 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a substrate such as a printed circuit board (PCB). For example, the apparatus 100 may be connected to a printed circuit board using interconnect structures 130 (e.g., arranged in a ball grid array), which may be melted to form a physical and electrical connection between the apparatus 100 and pads of the substrate.

The integrated circuit 105 may be electrically coupled to the interconnect structures 130 through an interconnect system that includes interconnect structures 130 formed on pads in the end regions 120 and a redistribution circuit 140 formed over and/or along a surface of the casing 125. In some implementations, an interconnect structure 135 is ball bond structure or a pillar structure that is directly conjoined with a pad in an end region 120 of a die 110. The redistribution circuit 140 may include a pattern of electrical traces (e.g., a redistribution layer of patterned copper or aluminum electrical traces) that is directly conjoined with the surface of the casing 125 along a contour. The contour may include a lateral portion 145 that is approximately parallel to lengthwise surfaces of the dies 110, and an angled portion 150 that is proximate to the stepped profile 115 and formed at an angle A1 relative to the lateral portion 145. The interconnect structures 130 and the redistribution circuit 140 may enable the integrated circuit 105 to receive signals from, and/or transmit signals to, a component that is external to the apparatus 100.

In some implementations, a protective layer 155 may be over and/or on the redistribution circuit 140. The protective layer 155 may be a solder mask or a passivation layer, among other examples.

As indicated above, FIG. 1 is provided as an example. Other examples may differ from what is described with regard to FIG. 1.

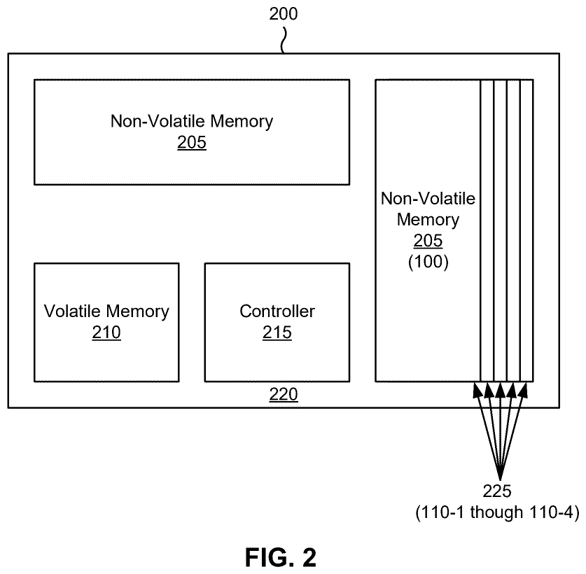

FIG. 2 is a diagram of an example memory device 200 that may be manufactured using techniques described herein. The memory device 200 may include one or more portions of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

In some implementations, the memory device 200 includes the apparatus 100 of FIG. 1. In such implementations, the apparatus 100 of FIG. 1 may include the non-volatile memory 205 (e.g., the semiconductor dies 225 of FIG. 2 may correspond to the dies 110 through 110-4 of FIG. 1) and be mounted to the substrate 220 through a surface mount (SMT) process that electrically couples the interconnect structures 130 with traces and/or pads of the substrate 220.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

As described in connection with FIG. 1, FIG. 2, and elsewhere herein, and in some implementations, an apparatus (e.g., the apparatus 100) includes a first integrated circuit die (e.g., the die 110-1) conjoined with a second integrated circuit die (e.g., the die 110-2) in a stack of integrated circuit dies (e.g., the integrated circuit 105), where the first integrated circuit die includes an end region (e.g., the end region 120) that extends beyond an edge of the second integrated circuit die. The apparatus includes an interconnect structure (e.g., the interconnect structure 135) that is conjoined with the end region and is electrically coupled to integrated circuitry of the first integrated circuit die. The apparatus includes a casing (e.g., the casing 125) that encapsulates at least a portion of the interconnect structure, at least a portion of the first integrated circuit die, and at least a portion of the second integrated circuit die. The apparatus includes an electrical trace (e.g., an electrical trace of the redistribution circuit 140) that is conjoined with a surface of the casing, is disposed along a contour of the casing (e.g., along the lateral portion 145 and along the angled portion 150), and is electrically coupled to the interconnect structure.

Additionally, or alternatively and in some implementations, a semiconductor package (e.g., the apparatus 100) includes a stack of integrated circuit dies (e.g., the dies 110-1 through 110-4) arranged in a shingled fashion to form a stepped profile (e.g., the stepped profile 115) along an end region of the stack. The semiconductor package includes a casing (e.g., the casing 125) that encapsulates the stack. The casing includes a first surface (e.g., the lateral portion 145) that is approximately planar and a second surface (e.g., the angled portion 150) that is angled relative to the first surface and that is proximate the stepped profile. The semiconductor package includes a redistribution circuit (e.g., the redistribution circuit 140) directly conjoined with the casing that includes a first portion that is disposed along the first surface and a second portion that is disposed along the second surface. The semiconductor package includes an array of external interconnect structures (e.g., the interconnect structures 130) that conjoins with the first portion and that extends away from the casing, and an array of internal interconnect structures (e.g., the interconnect structures 135) that conjoins with the second portion and that extends into the casing to connect with the stack.

In these ways, the implementations are advanced over conventional TSV and wire bonding stacking methods by offering a more efficient and scalable approach for die stacking. The implementations may improve the quality and/or the reliability of the semiconductor device, thereby reducing an amount of resources used to support a market consuming the semiconductor device (e.g., raw materials, semiconductor manufacturing tools, labor, and/or computing resources).

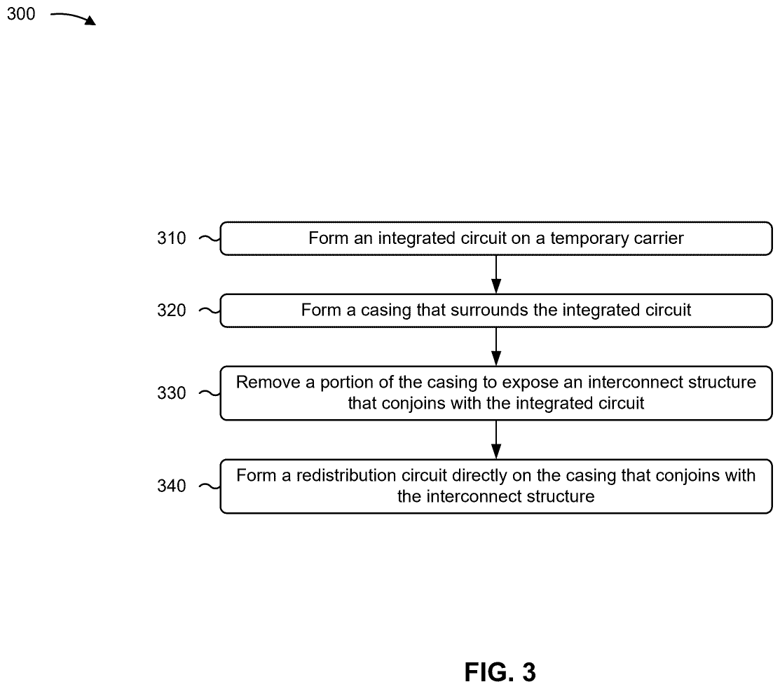

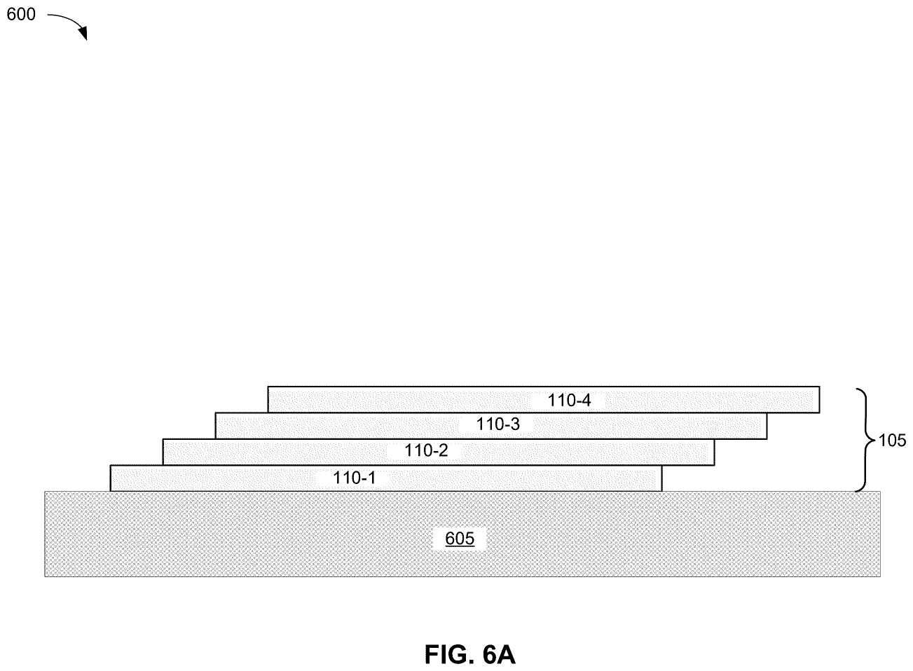

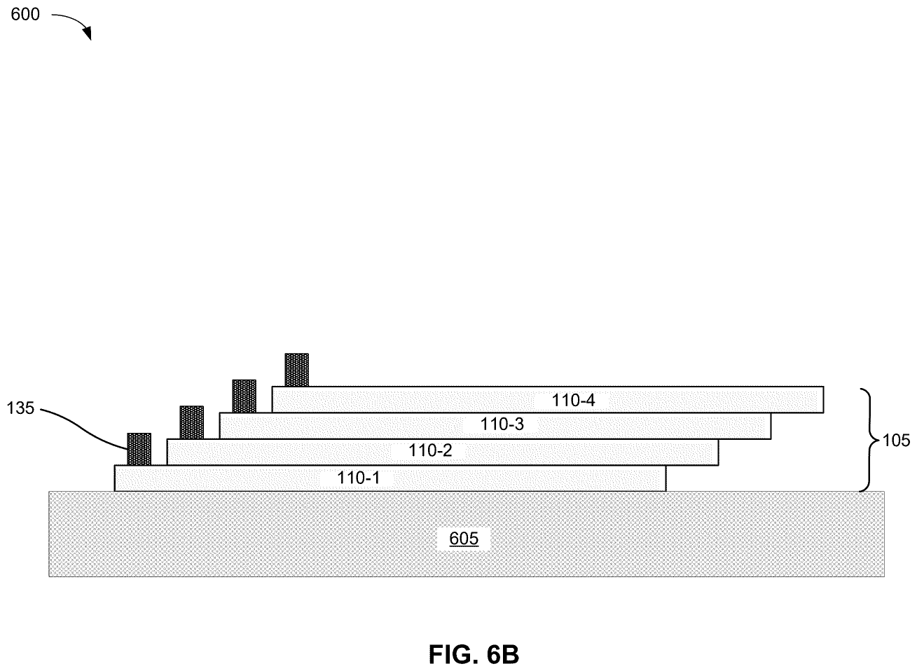

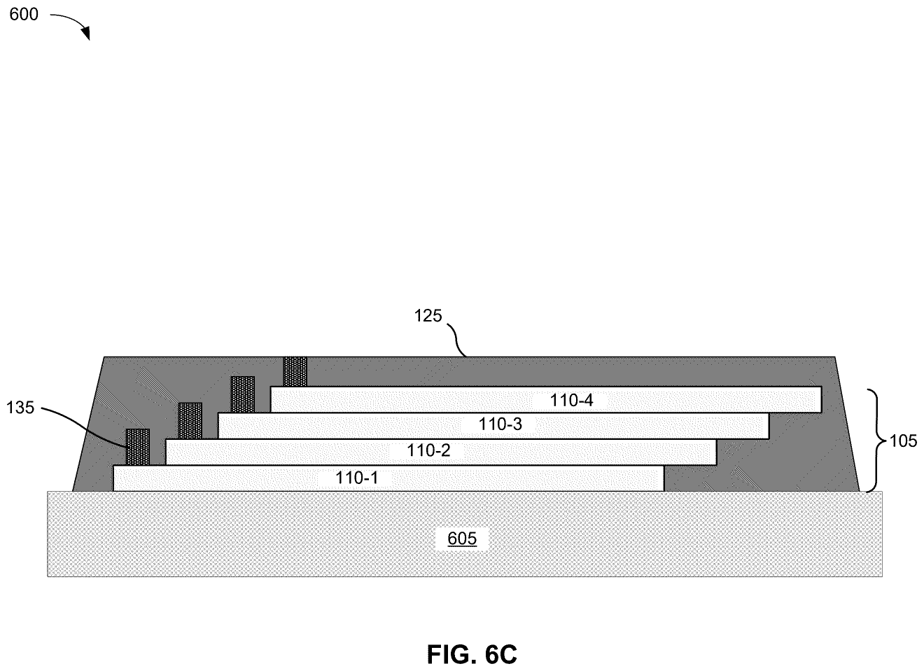

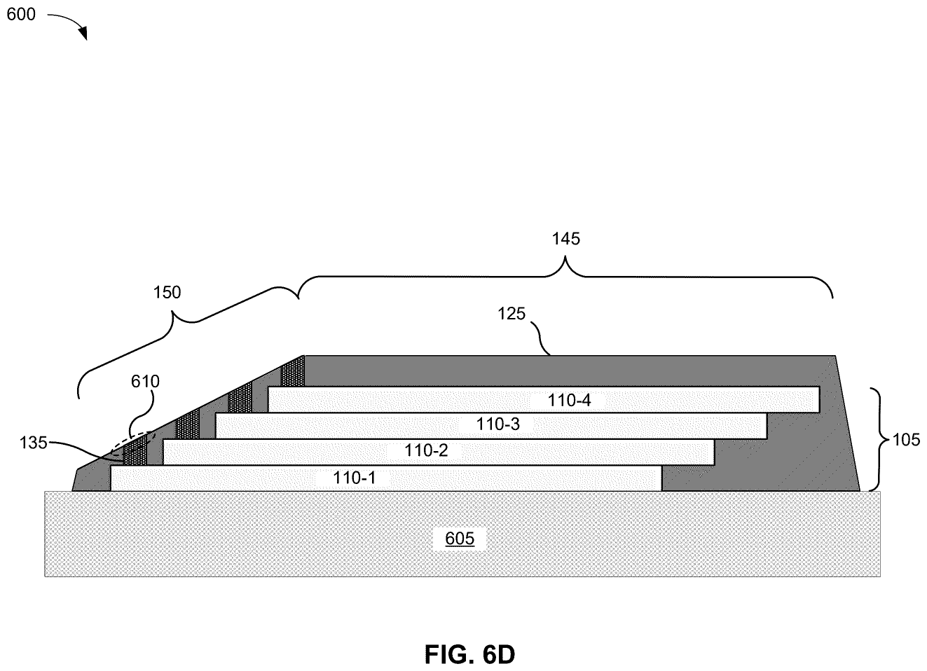

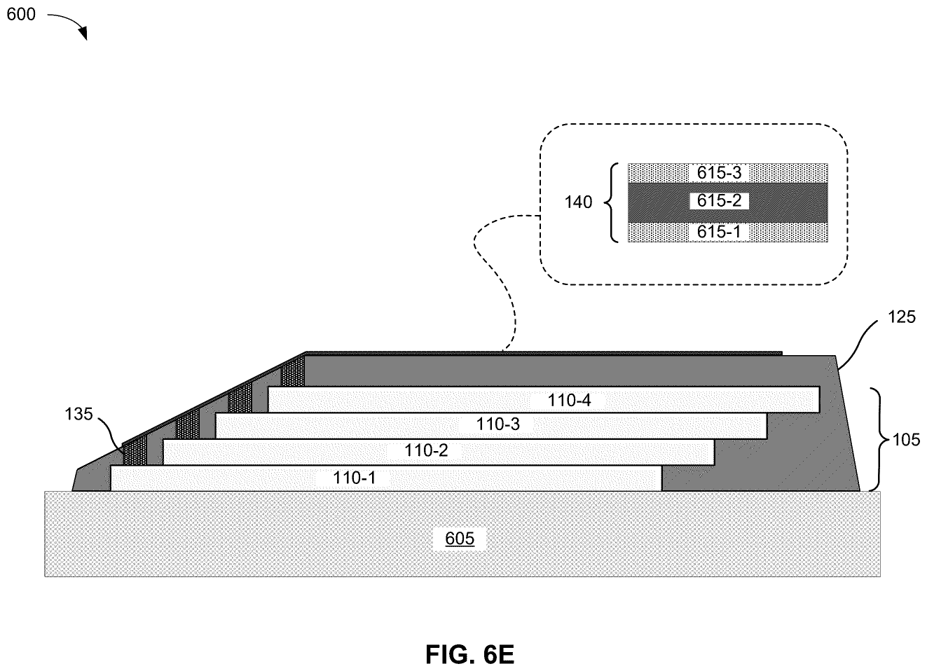

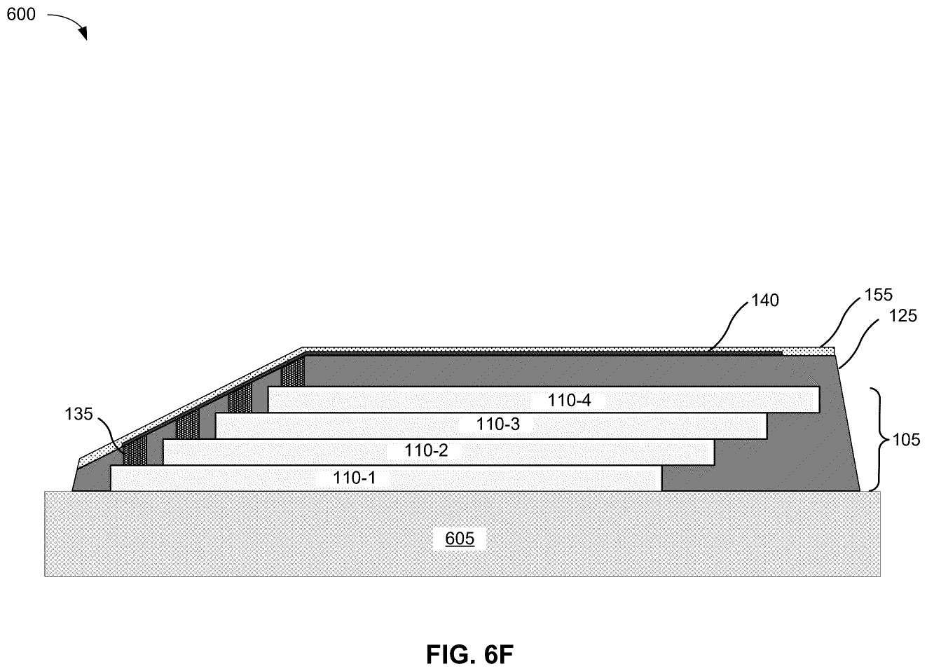

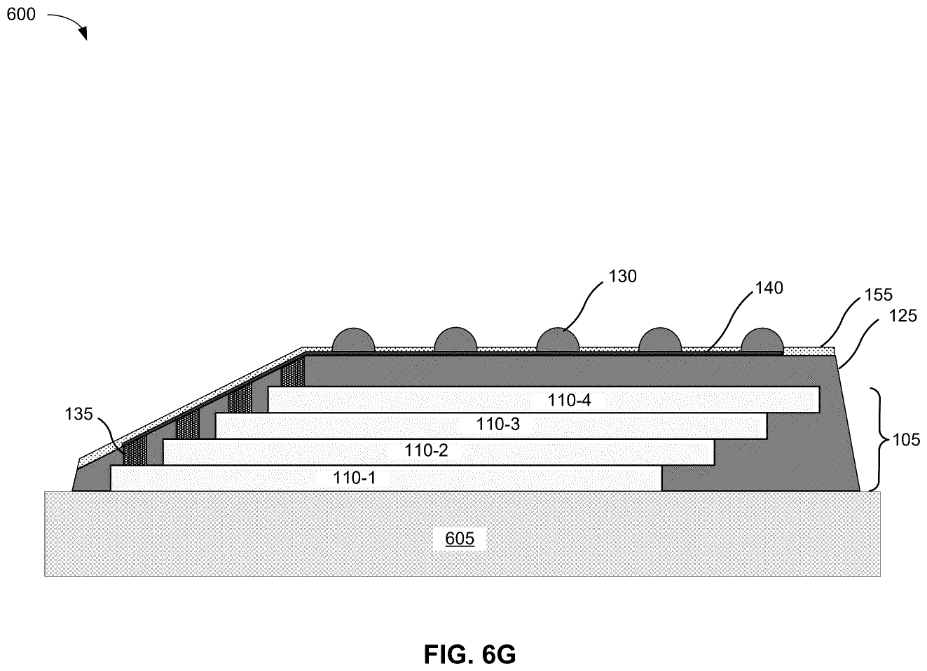

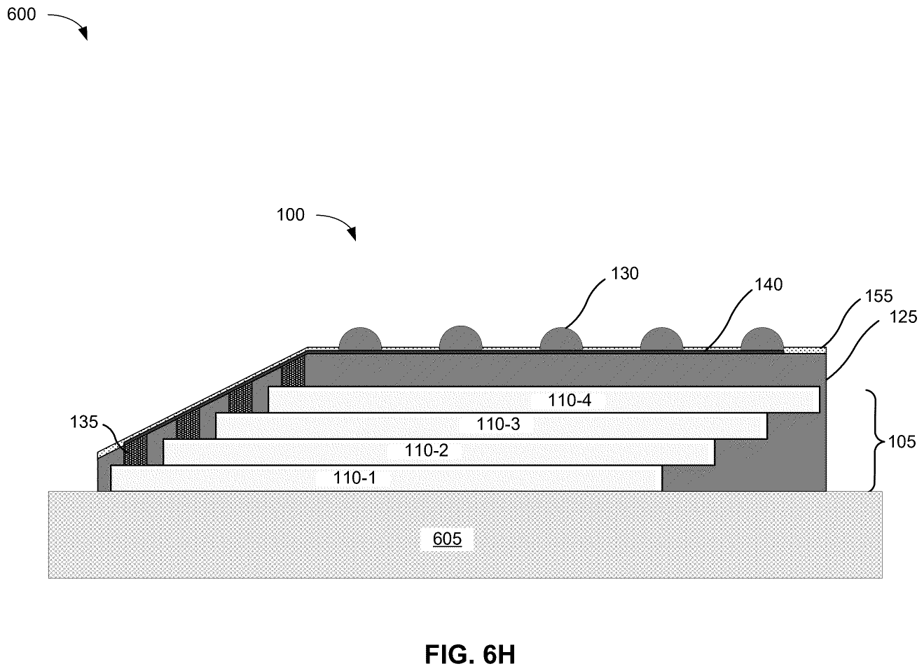

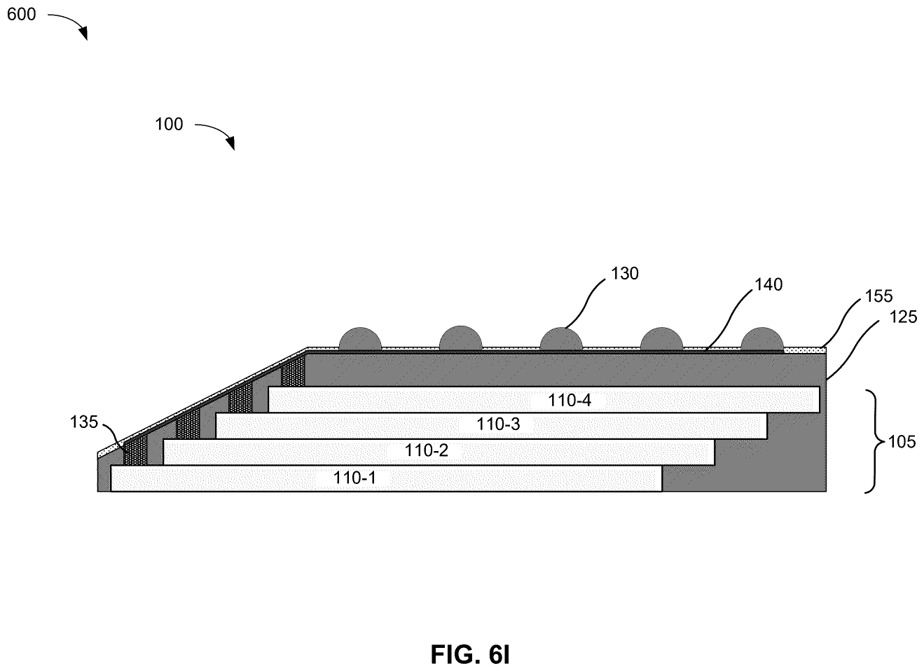

FIG. 3 is a flowchart of an example method 300 of forming an integrated assembly or memory device having a stacked die substrate-less semiconductor package (e.g., the apparatus 100). In some implementations, and as described in greater detail in connection with FIGS. 6A through 6I, one or more process blocks of FIG. 3 may be performed by various semiconductor manufacturing equipment.

As shown in FIG. 3, the method 300 may include forming an integrated circuit (e.g., the integrated circuit 105) on a temporary carrier (block 310). As further shown in FIG. 3, the method 300 may include forming a casing (e.g., the casing 125) that surrounds the integrated circuit (block 320). As further shown in FIG. 3, the method 300 may include removing a portion of the casing to expose an interconnect structure (e.g., the interconnect structure 135) that conjoins with the integrated circuit (block 330). As further shown in FIG. 3, the method 300 may include forming a redistribution circuit (e.g., the redistribution circuit 140) directly on the casing that conjoins with the interconnect structure (block 340).

The method 300 may include additional aspects, such as any single aspect or any combination of aspects described below and/or in connection with one or more other methods described elsewhere herein.

In a first aspect, forming the integrated circuit includes placing an integrated circuit die that includes the interconnect structure over the temporary carrier.

In a second aspect, alone or in combination with the first aspect, placing the integrated circuit die is part of a die stacking operation that forms a stack of integrated circuit dies (e.g., the dies 110-1 through 110-4) on the temporary carrier.

In a third aspect, alone or in combination with one or more of the first and second aspects, forming the integrated circuit includes placing an integrated circuit die over the temporary carrier, and forming the interconnect structure on the integrated circuit die.

In a fourth aspect, alone or in combination with one or more of the first through third aspects, placing the integrated circuit die is part of a die stacking operation that forms a stack of integrated circuit dies on the temporary carrier.

In a fifth aspect, alone or in combination with one or more of the first through fourth aspects, forming the casing includes forming the casing using a film-based molding operation.

In a sixth aspect, alone or in combination with one or more of the first through fifth aspects, forming the redistribution circuit includes sputtering at least one conductive layer onto the casing through a mask above the casing, wherein the mask patterns the redistribution circuit from the at least one conductive layer.

In a seventh aspect, alone or in combination with one or more of the first through sixth aspects, forming the redistribution circuit includes sputtering at least one conductive layer onto the casing, and using a lithography process to pattern the redistribution circuit from the at least one conductive layer.

In an eighth aspect, alone or in combination with one or more of the first through seventh aspects, removing the portion of the casing includes removing the portion of the casing using a grinding tool with a beveled profile, wherein removing the portion forms an angled, exposed surface of the interconnect structure.

In a ninth aspect, alone or in combination with one or more of the first through eighth aspects, removing the portion of the casing includes removing the portion of the casing using a grinding tool that is oriented at an angle relative to the casing, wherein removing the portion forms an angled, exposed surface of the interconnect structure.

In a tenth aspect, alone or in combination with one or more of the first through ninth aspects, the portion of the casing is a first portion, and the method 300 includes removing a second portion of the casing as part of defining edges of a semiconductor package (e.g., the apparatus 100) that includes the integrated circuit, the casing, the interconnect structure, and the redistribution circuit.

In an eleventh aspect, alone or in combination with one or more of the first through tenth aspects, the interconnect structure is a first interconnect structure, and the method 300 includes forming a protective layer (e.g., the protective layer 155) over the redistribution circuit, and forming a second interconnect structure (e.g., the interconnect structure 130) over a pad of the redistribution circuit through an opening in the protective layer.

In a twelfth aspect, alone or in combination with one or more of the first through eleventh aspects, forming the protective layer includes forming a solder mask, or forming a passivation layer.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the apparatus 100, an integrated assembly that includes the apparatus 100, any part described herein of the apparatus 100, and/or any part described herein of an integrated assembly that includes the apparatus 100. For example, the method 300 may include forming one or more parts of the memory device 200.

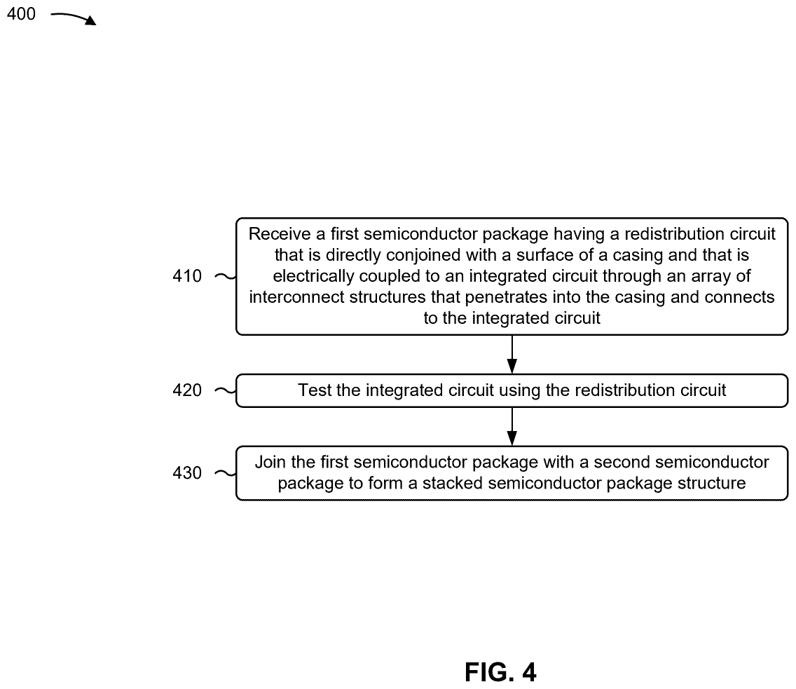

FIG. 4 is a flowchart of an example method 400 of forming an integrated assembly or memory device having a stacked die substrate-less semiconductor package (e.g., the apparatus 100). In some implementations, and as described in greater detail in connection with FIGS. 6A through 6I, one or more process blocks of FIG. 4 may be performed by various semiconductor manufacturing equipment.

As shown in FIG. 4, the method 400 may include receiving a first semiconductor package (e.g., the apparatus 100) having a redistribution circuit (e.g., the redistribution circuit 140) that is directly conjoined with a surface of a casing (e.g., the casing 125) and that is electrically coupled to an integrated circuit (e.g., the integrated circuit 105) through an array of interconnect structures (e.g., the interconnect structures 135) that penetrates into the casing and connects to the integrated circuit (block 410). As further shown in FIG. 4, the method 400 may include testing the integrated circuit using the redistribution circuit (block 420). As further shown in FIG. 4, the method 400 may include joining the first semiconductor package with a second semiconductor package to form a stacked semiconductor package structure (block 430).

The method 400 may include additional aspects, such as any single aspect or any combination of aspects described below and/or in connection with one or more other methods described elsewhere herein.

In a first aspect, testing the integrated circuit includes testing the integrated circuit by probing pads of the redistribution circuit.

In a second aspect, alone or in combination with the first aspect, testing the integrated circuit includes testing the integrated circuit by probing interconnect structures connected to the redistribution circuit.

In a third aspect, alone or in combination with one or more of the first and second aspects, the method 400 includes mounting the stacked semiconductor package structure to a circuit board.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the apparatus 100, an integrated assembly that includes the apparatus 100, any part described herein of the apparatus 100, and/or any part described herein of an integrated assembly that includes the apparatus 100. For example, the method 400 may include forming one or more parts of the memory device 200.

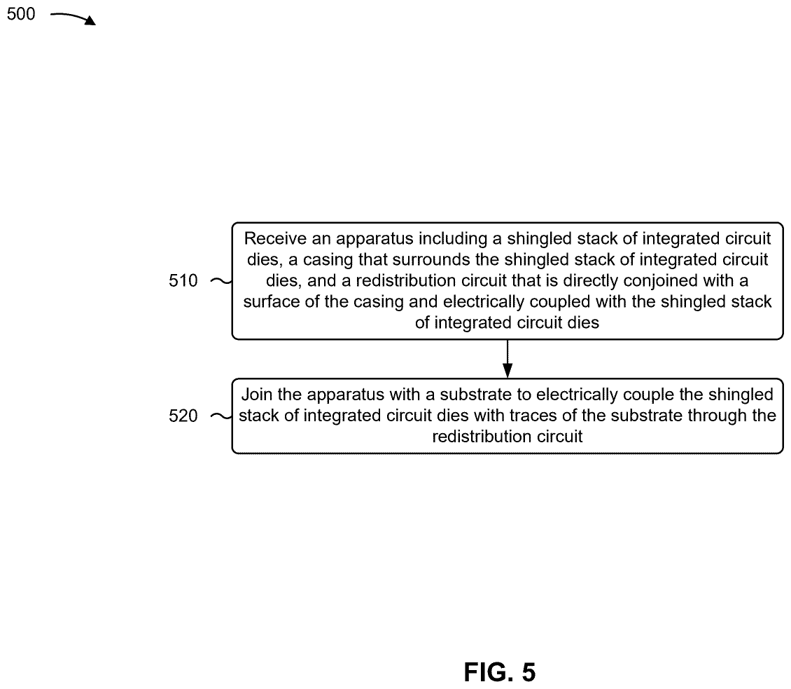

FIG. 5 is a flowchart of an example method 500 of forming an integrated assembly or memory device having a stacked die substrate-less semiconductor package. In some implementations one or more process blocks of FIG. 5 may be performed by various semiconductor manufacturing equipment at a surface mount (SMT) manufacturing facility.

As shown in FIG. 5, the method 500 may include receiving an apparatus (e.g., the apparatus) including a shingled stack of integrated circuit dies (e.g., the dies 110-1 through 110-4), a casing (e.g., the casing 125) that surrounds the shingled stack of integrated circuit dies, and a redistribution circuit (e.g., the redistribution circuit 140) that is directly conjoined with a surface of the casing and electrically coupled with the shingled stack of integrated circuit dies (block 510). As further shown in FIG. 5, the method 500 may include joining the apparatus with a substrate (e.g., the substrate 220) to electrically couple the shingled stack of integrated circuit dies with traces of the substrate through the redistribution circuit (block 520).

The method 500 may include additional aspects, such as any single aspect or any combination of aspects described below and/or in connection with one or more other methods described elsewhere herein.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the apparatus 100, an integrated assembly that includes the apparatus 100, any part described herein of the apparatus 100, and/or any part described herein of an integrated assembly that includes the apparatus 100. For example, the method 500 may include forming one or more parts of the memory device 200.

FIGS. 6A through 6I are diagrammatic views showing formation of an example apparatus (e.g., the apparatus 100) at example process stages of an example process 600 of forming the apparatus. In some implementations, the example process described below in connection with FIGS. 6A through 6I may correspond to the method 300, one or more blocks of the method 300, the method 400, one or more blocks of the method 400, the method 500, and/or one or more blocks of the method 500. However, the process described below is an example, and other example processes may be used to form the apparatus 100, an integrated assembly that includes the apparatus 100, and/or one or more parts of the apparatus 100 and/or the integrated assembly.

As shown in FIG. 6A, the process 600 may include receiving a temporary carrier 605 and forming the integrated circuit 105 over and/or on the temporary carrier 605. The temporary carrier 605 may be a ceramic carrier wafer or a glass carrier wafer, among other examples. As an example, forming the integrated circuit 105 may include a die-attach tool forming the integrated circuit 105 by placing and/or stacking the dies 110-1 through 110-4. In some implementations, an adhesive (e.g., a die attach film) is used between the dies 110-1 through 110-4.

As shown in FIG. 6B, the process 600 may include forming one or more arrays of the interconnect structures 135 on the dies 110-1 through 110-4, where the interconnect structures 135 conjoin with integrated circuitry included on the dies 110-1 through 110-4. As an example, forming the of interconnect structures 135 may include a lithography tool set forming a mask structure over and/or on the dies 110-1 through 110-4, and an electroplating tool forming pillar structures through openings in the mask structure and on pads and/or traces of the dies 110-1 through 110-4. As another example, forming the interconnect structures 135 may include a wire bonding tool forming ball bond structures on pads and/or traces of the dies 110-1 through 110-4. Alternatively, and in some implementations, the interconnect structures 135 may be pre-formed on the dies 110-1 through 110-4 prior to forming the integrated circuit 105 (e.g., prior to placing and/or stacking the dies 110-1 through 110-4).

As shown in FIG. 6C, the process 600 may include forming the casing 125 to encapsulate the integrated circuit 105 and/or the interconnect structures 135. As an example, forming the casing 125 may include a molding tool performing a film-based molding operation or another suitable molding operation to form the casing 125.

As shown in FIG. 6D, the process 600 may include removing a portion of the casing 125 to expose the interconnect structures 135. As an example, a grinding tool that is oriented at an angle relative to the casing 125 may perform a grinding operation that forms the angled portion 150 and angled, exposed surfaces 610 of the interconnect structures 135. Alternatively, and as another example, a grinding tool that includes a beveled profile may perform a grinding operation that forms the angled portion 150 and the angled, exposed surfaces 610 of the interconnect structures 135.

As shown in FIG. 6E, the process 600 may include forming the redistribution circuit 140 directly on the casing 125, such that the redistribution circuit 140 directly conjoins with a surface of the casing 125 along a contour of the casing 125. As an example, forming the redistribution circuit 140 may include a deposition tool performing a deposition operation that sputters at least one conductive layer of the redistribution circuit 140 onto the casing 125 through a mask above the casing 125, where the mask patterns the redistribution circuit 140 from the at least one conductive layer. Alternatively, and as another example, forming the redistribution circuit 140 may include a deposition tool performing a deposition operation that sputters at least one conductive layer onto the casing 125, and using a set of lithography tools to pattern the redistribution circuit 140 from the at least one conductive layer. As shown in FIG. 6E, the redistribution circuit 140 may include multiple conductive layers 615, including a conductive layer 615-1 that is an adhesion layer, a conductive layer 615-2 that is a core conductive layer, and a conductive layer 615-3 that is a capping layer.

In some implementations, and after formation of the redistribution circuit 140, the process 600 may include testing of the integrated circuit 105. For example, and after formation of the redistribution circuit 140, a test tool may probe pads and/or traces of the redistribution circuit 140 to perform a speed test or a reliability test of the integrated circuit 105. In some implementations, testing the integrated circuit 105 may include accessing built in self-test (BIST) integrated circuitry and/or repair integrated circuitry included on the dies 110-1 through 110-4.

As shown in FIG. 6G, the process 600 may include forming the protective layer 155 over and/or on the redistribution circuit 140. As an example, forming the protective layer 155 may include a printing tool performing a printing operation to form a solder mask layer over and/or on the redistribution circuit 140. Alternatively, and as another example, forming the protective layer 155 may include a deposition tool performing a chemical vapor deposition (CVD) or physical vapor deposition (PVD) operation to form a passivation layer over and/or on the redistribution circuit 140.

As shown in FIG. 6H, the process 600 may include forming the interconnect structures 130 through openings in the protective layer 155 and on pads of the redistribution circuit 140. As an example, forming the interconnect structures 130 may include a solder ball attach tool performing a ball attach operation to place solder balls on pads of the redistribution circuit 140 through openings in the protective layer 155. Alternatively, and as another example, forming the interconnect structures 130 may include an electroplating tool performing an electroplating operation to form pillar structures on pads of the redistribution circuit 140 through openings in the protective layer 155.

In some implementations, and after formation of the interconnect structures 130, the process 600 may include testing of the integrated circuit 105. For example, and after formation of the interconnect structures 130, a test tool may probe the interconnect structures 130 to perform a speed test or a reliability test of the integrated circuit 105. In some implementations, testing the integrated circuit 105 may include accessing built in self-test (BIST) integrated circuitry and/or repair integrated circuitry include on the dies 110-1 through 110-4.

In some implementations, and after formation of the interconnect structures 130, the process 600 may include removing additional portions of the casing 125 to define edges of the apparatus 100. For example, and after formation of the interconnect structures 130, a dicing tool may perform a dicing operation that defines edges of the apparatus 100.

As shown in FIG. 6I, the process 600 may include removing the apparatus 100 from the temporary carrier 605. As an example, removing the apparatus 100 from the temporary carrier 605 may include using a thermal tool to perform a heating operation that heats the temporary carrier 605, and using a pick and place tool to perform a removal operation that removes the apparatus 100 from the temporary carrier 605.

As indicated above, the process steps described in connection with FIGS. 6A through 6I are provided as examples. Other examples may differ from what is described with respect to FIGS. 6A through 6I.

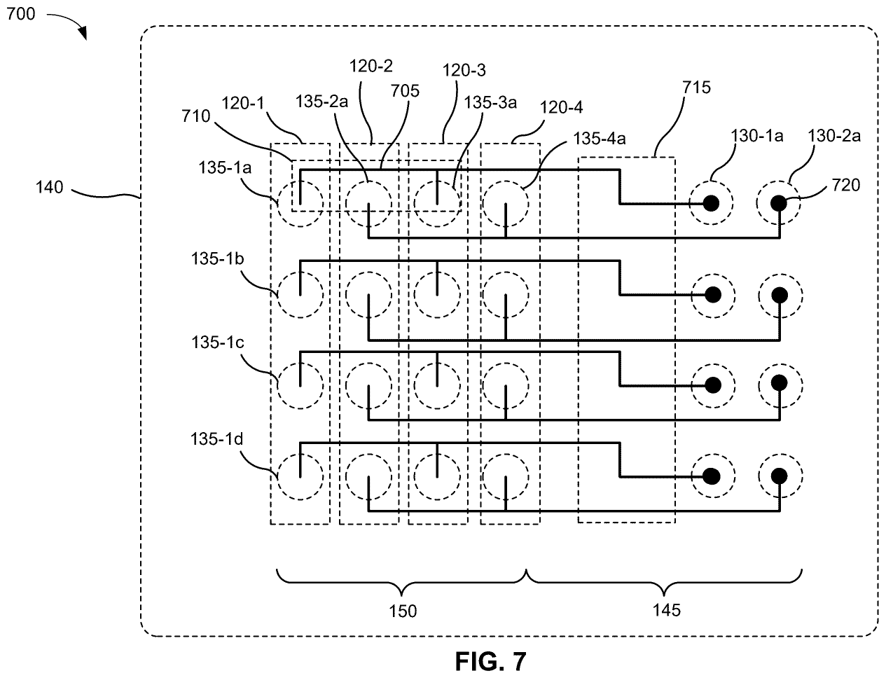

FIG. 7 is a diagram of an example circuit layout 700 of a redistribution circuit (e.g., the redistribution circuit 140) described herein. The circuit layout 700 shows a plan view of the redistribution circuit 140 in relation to the lateral portion 145 and the angled portion 150 as described in connection with FIG. 1. The circuit layout 700 is further shown in relation to end regions 120-1 through 120-4 (e.g. including arrays of the interconnect structures 135) and an array of the interconnect structures 130.

As shown in FIG. 7, the redistribution circuit 140 includes a pattern of electrical traces 705. In some implementations, an electrical trace 705 may electrically couple channels of one or more integrated circuit dies. For example, and as shown in FIG. 7, the portion 710 of the electrical trace 705 (e.g., a portion of the redistribution circuit 140 along the angled portion 150) electrically couples the interconnect structure 135-1a (which may electrically couple with a channel of the die 110-1 of FIG. 1) and the interconnect structure 135-3a (which may electrically couple with a channel of the die 110-3 of FIG. 1).

In some implementations, electrical coupling of channels of integrated circuit dies may include staggering and/or skipping among integrated circuit dies including in an integrated circuit. For example, and as shown in FIG. 7, interconnect structure 135-2a (e.g., which may electrically couple with a channel of the die 110-2 of FIG. 2) is not included as part of the portion 710 that electrically couples the interconnect structure 135-a1 and the interconnect structure 135-a3.

In some implementations, electrical coupling of the channels may be inter-package (e.g., within a single apparatus 100). In some implementations, electrical coupling of the channels may be intra-package (e.g., distributed across a stacked semiconductor package structure including multiples of the apparatus 100).

As shown in FIG. 7, the redistribution circuit 140 may include a portion 715 that includes a bus connecting to one or more pads 720. In some implementations, and as described in connection with FIG. 6G, the interconnect structures 130s may be formed on and/or over the pads 720.

As indicated above, FIG. 7 is provided as an example. Other examples may differ from what is describe with regard to FIG. 7.

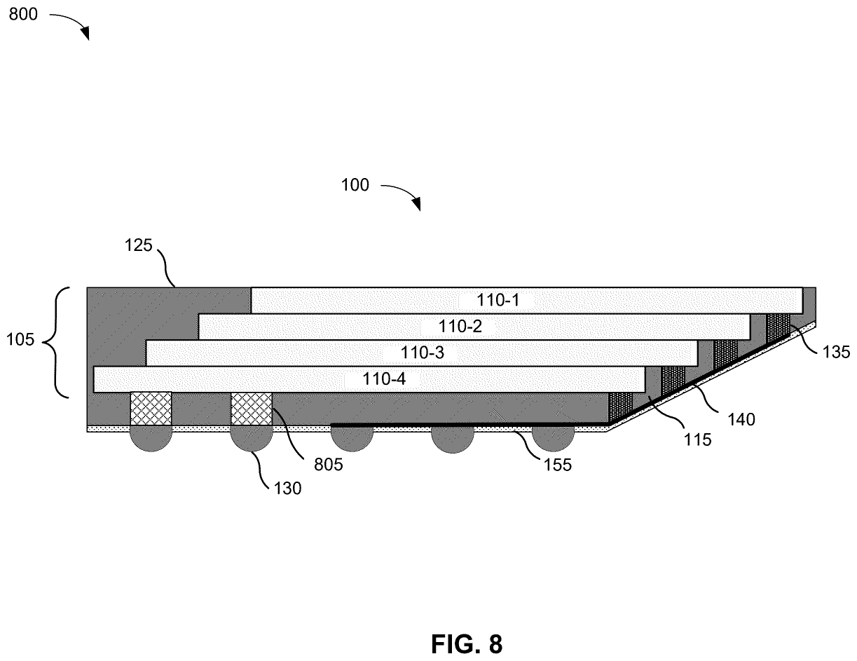

FIG. 8 is a diagram of an example implementation 800 described herein. In FIG. 8, the apparatus 100 includes one or more interconnect structures 805 that are conjoined with the die 110-4 (e.g., cojoined with traces and/or pads of the die 110-4). In some implementations, the apparatus 100 of FIG. 8 is formed using one or more techniques substantially similar to those described in connection with FIGS. 3 through 6A.

In some implementations, the interconnect structures 805 mechanically couple to the interconnect structures 130 to provide a thermally-conductive path to manage a thermal performance of the integrated circuit 105 by conducting heat that is generated by the integrated circuit 105 away from the integrated circuit 105. Additionally, or alternatively and in some implementations, the interconnect structures 805 electrically couples to the interconnect structures 130 to manage a power performance of the integrated circuit 105.

Additionally, or alternatively and as part of thermal management of the integrated circuit 105, the interconnect structures 805 may mechanically couple with a portion of the redistribution circuit 140. Additionally, or alternatively and as part of power management of the integrated circuit 105, the interconnect structures 805 may electrically couple with a portion of the redistribution circuit 140.

As indicated above, FIG. 8 is provided as an example. Other examples may differ from what is described with regard to FIG. 8.

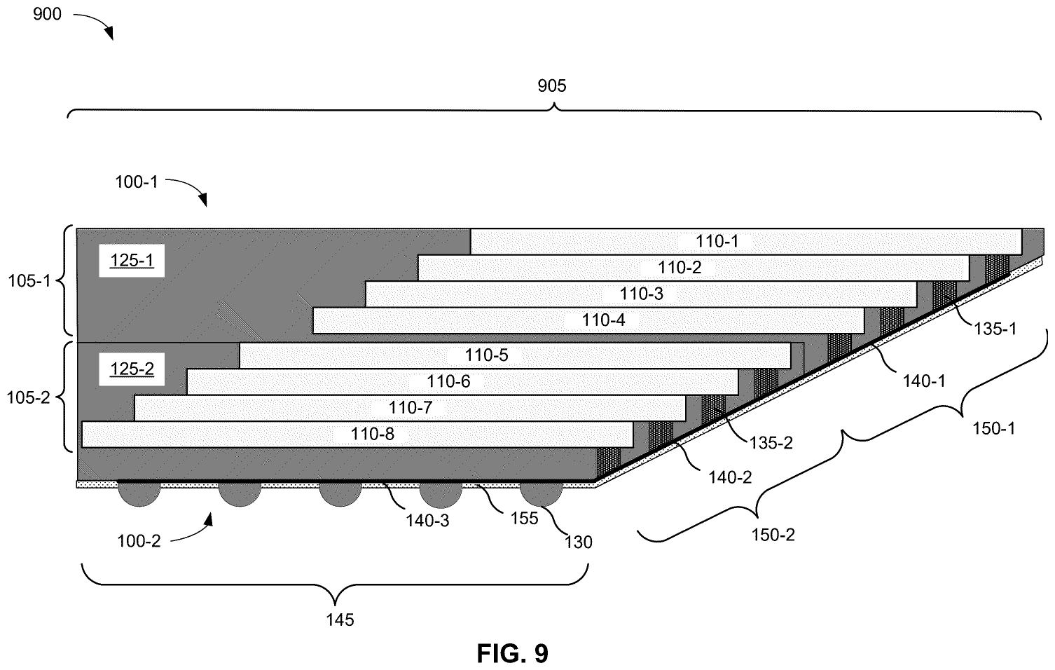

FIG. 9 is a diagram of an example implementation 900 described herein. In FIG. 9, the apparatus 100-1 and the apparatus 100-2 are joined to form a stacked semiconductor package structure 905. In some implementations, the apparatus 100-1 and/or the apparatus 100-2 of FIG. 9 is formed using one or more techniques substantially similar to those described in connection with FIGS. 3 through 6A.

As shown in FIG. 9, the apparatus 100-1 includes the integrated circuit 105-1 (e.g., the dies 110-1 through 110-4), the casing 125-1 that encapsulates the integrated circuit 105-1, the interconnect structures 135-1, and a portion of the redistribution circuit 140-1 that is over and/or along the angled portion 150-1. As further shown in FIG. 9, the apparatus 100-2 includes the integrated circuit 105-2 (e.g., the dies 110-5 through 110-8), the casing 125-2 that encapsulates the integrated circuit 105-2, the interconnect structures 135-2, and a portion of the redistribution circuit 140-3 that is over and/or along the angled portion 150-2. The apparatus 100-2 further includes the lateral portion 145 and the interconnect structures 130.

As shown in FIG. 9, the protective layer 155 is over and/or along surfaces of the apparatus 100-1 and the apparatus 100-2. Furthermore, the portion of the redistribution circuit 140-3 is over and/or along the lateral portion 145, the portion of the redistribution circuit 140-2 is over and/or along the angled portion 150-2, and the portion of the redistribution circuit 140-3 is over and/or along the angled portion 150-3. In some implementations, and as described in connection with FIG. 7, the portion of the redistribution circuit 140-2 and the portion of the redistribution circuit 140-1 may form intra-package channel connections between the integrated circuit 105-2 and the integrated circuit 105-1.

As indicated above, FIG. 9 is provided as an example. Other examples may differ from what is described with regard to FIG. 9 (e.g., the stacked semiconductor package structure 905 may be extended to include three, four, or even more quantities of the apparatus 100).

As described in connection with FIG. 2, FIG. 8, FIG. 9, and elsewhere herein, and in some implementations, an integrated assembly (e.g., the memory device 200) may include a printed circuit board (e.g., the substrate 220) and a stacked semiconductor package structure (e.g., the stacked semiconductor package structure 905) mounted to the printed circuit board. The stacked semiconductor package structure includes a first substrate-less semiconductor package (e.g., the apparatus 100-1) that includes a first integrated circuit (e.g., the integrated circuit 105-1), a first casing (e.g., the casing 125-1) that encapsulates the first integrated circuit, and a first interconnect structure (e.g., the interconnect structure 135-1) that extends from the first integrated circuit to a first angled surface (e.g., the angled portion 150-1) of the first casing. The stacked semiconductor package structure includes a second substrate-less semiconductor package (e.g., the apparatus 100-2) stacked with the first substrate-less semiconductor package that includes a second integrated circuit (e.g., the integrated circuit 105-2), a second casing (e.g., the casing 125-2) that encapsulates the second integrated circuit, a second interconnect structure (e.g., the interconnect structure 135-2) that extends from the second integrated circuit to a second angled surface (e.g., the angled portion 150-2) of the second casing, and a redistribution circuit (e.g., the redistribution circuit 140) including portions that are directly conjoined with the first casing and the second casing and include a first portion (e.g., the redistribution circuit 140-1) that is along the first angled surface and that conjoins with the first interconnect structure and a second portion (e.g., the redistribution circuit 140-2) that is along the second angled surface and that conjoins with the second interconnect structure.

In these ways, the integrated assembly is advanced over conventional TSV and wire bonding stacking methods by offering a more efficient and scalable approach for die stacking. The substrate-less construction improves thermal conductance and reduces signal transit distances, thereby enhancing signal integrity and thermal management within the device. By improving the quality and/or the reliability of the semiconductor device, an amount of resources used to support a market consuming the semiconductor device (e.g., raw materials, semiconductor manufacturing tools, labor, and/or computing resources) is reduced. Furthermore, the integrated assembly permits the completion of comprehensive electrical testing before final assembly, supports adaptable scaling for various package configurations with minimal design changes, and streamlines the manufacturing process, thereby promoting resource conservation in the production of semiconductor devices.

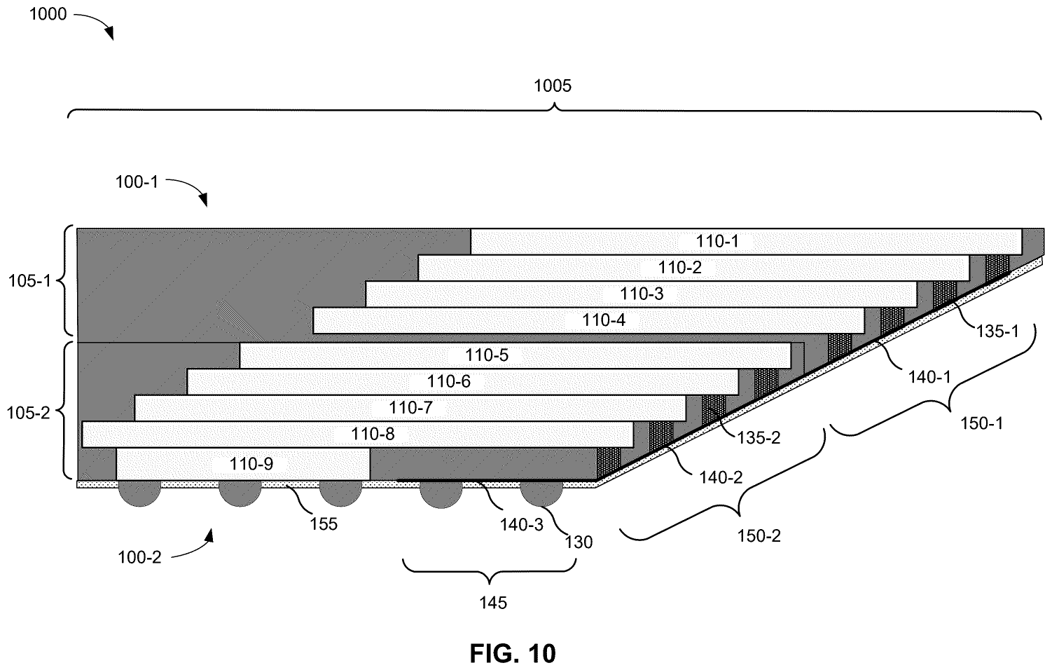

FIG. 10 is a diagram of an example implementation 1000 described herein. In FIG. 10, the apparatus 100-1 and the apparatus 100-2 are joined to form a stacked semiconductor package structure 1005. In some implementations, the apparatus 100-1 and/or the apparatus 100-2 of FIG. 9 is formed using one or more techniques substantially similar to those described in connection with FIGS. 3 through 6A.

As shown in FIG. 10, the apparatus 100-1 includes the integrated circuit 105-1 (e.g., the dies 110-1 through 110-4), the casing 125-1 that encapsulates the integrated circuit 105-1, the interconnect structures 135-1, and the portion of the redistribution circuit 140-1 that is over and/or along the angled portion 150-1. As further shown in FIG. 9, the apparatus 100-2 includes the integrated circuit 105-2 (e.g., the dies 110-5 through 110-9), the casing 125-2 that encapsulates the integrated circuit 105-2, the interconnect structures 135-2, and the portion of the redistribution circuit 140-3 that is over and/or along the angled portion 150-2. The apparatus 100-2 further includes the lateral portion 145 and the interconnect structures 130.

In FIG. 10, the die 110-9 may include interface integrated circuitry. In some implementations, the die 110-9 and/or the interface integrated circuitry are directly coupled with the interconnect structures 130. Additionally, or alternatively and in some implementations, the die 110-9 may include integrated circuit directly coupled with a portion of the redistribution circuit 140.

As shown in FIG. 10, the protective layer 155 is over and/or along surfaces of the apparatus 100-1 and the apparatus 100-2. Furthermore, the portion of the redistribution circuit 140-3 is over and/or along the lateral portion 145, the portion of the redistribution circuit 140-2 is over and/or along the angled portion 150-2, and the portion of the redistribution circuit 140-1 is over and/or along the angled portion 150-1. In some implementations, and as described in connection with FIG. 7, the portion of the redistribution circuit 140-2 and the portion of the redistribution circuit 140-1 may form intra-package channel connections between the integrated circuit 105-2 and the integrated circuit 105-1.

In some implementations, the stacked semiconductor package structure 1005 may provide an increase in module level channels. Additionally, or alternatively and in some implementations, the stacked semiconductor package structure 1005 may reduce an amount of interconnects needed to mount the stacked semiconductor package structure 1005 to a printed circuit board (e.g., reduce an amount of the interconnects 130 needed to mount the stacked semiconductor package structure 1005 to the substrate 220).

As indicated above, FIG. 10 is provided as an example. Other examples may differ from what is described with regard to FIG. 10.

Techniques described in connection with FIGS. 1 through 10 are advanced over conventional TSV and wire bonding stacking methods by offering a more efficient and scalable approach for die stacking. The substrate-less construction improves thermal conductance and reduces signal transit distances, thereby enhancing signal integrity and thermal management within the device. By improving the quality and/or the reliability of the semiconductor device, an amount of resources used to support a market consuming the semiconductor device (e.g., raw materials, semiconductor manufacturing tools, labor, and/or computing resources) is reduced. Furthermore, the design permits the completion of comprehensive electrical testing before final assembly, supports adaptable scaling for various package configurations with minimal design changes, and streamlines the manufacturing process, thereby promoting resource conservation in the production of semiconductor devices.

In some implementations, an apparatus includes a first integrated circuit die conjoined with a second integrated circuit die in a stack of integrated circuit dies, wherein the first integrated circuit die includes an end region that extends beyond an edge of the second integrated circuit die; an interconnect structure that is conjoined with the end region and is electrically coupled to integrated circuitry of the first integrated circuit die; a casing that encapsulates at least a portion of the interconnect structure, at least a portion of the first integrated circuit die, and at least a portion of the second integrated circuit die; and an electrical trace that is conjoined with a surface of the casing, is disposed along a contour of the casing, and is electrically coupled to the interconnect structure.

In some implementations, a semiconductor package includes a stack of integrated circuit dies arranged in a shingled fashion to form a stepped profile along an end region of the stack; a casing that encapsulates the stack, comprising: a first surface that is approximately planar; and a second surface that is angled relative to the first surface and that is proximate the stepped profile; a redistribution circuit directly conjoined with the casing, comprising: a first portion that is disposed along the first surface; and a second portion that is disposed along the second surface; an array of external interconnect structures that conjoins with the first portion and that extends away from the casing; and an array of internal interconnect structures that conjoins with the second portion and that extends into the casing to connect with the stack.

In some implementations, an apparatus includes a printed circuit board; and a stacked semiconductor package structure mounted to the printed circuit board, comprising: a first substrate-less semiconductor package, comprising: a first integrated circuit; a first casing that encapsulates the first integrated circuit; and a first interconnect structure that extends from the first integrated circuit to a first angled surface of the first casing; a second substrate-less semiconductor package stacked with the first substrate-less semiconductor package, comprising: a second integrated circuit; and a second casing that encapsulates the second integrated circuit; a second interconnect structure that extends from the second integrated circuit to a second angled surface of the second casing; and a redistribution circuit including portions that are directly conjoined with the first casing and the second casing, comprising: a first portion that is along the first angled surface and that conjoins with the first interconnect structure, a second portion that is along the second angled surface and that conjoins with the second interconnect structure.

In some implementations, a method includes forming an integrated circuit on a temporary carrier; forming a casing that surrounds the integrated circuit; removing a portion of the casing to expose an interconnect structure that conjoins with the integrated circuit; and forming a redistribution circuit directly on the casing that conjoins with the interconnect structure.

In some implementations, a method includes receiving a first semiconductor package having a redistribution circuit that is directly conjoined with a surface of a casing and that is electrically coupled to an integrated circuit through an array of interconnect structures that penetrates into the casing and connects to the integrated circuit; testing the integrated circuit using the redistribution circuit; and joining the first semiconductor package with a second semiconductor package to form a stacked semiconductor package structure.

In some implementations, a method includes receiving an apparatus including a shingled stack of integrated circuit dies, a casing that surrounds the shingled stack of integrated circuit dies, and a redistribution circuit that is directly conjoined with a surface of the casing and electrically coupled with the shingled stack of integrated circuit dies; joining the apparatus with the substrate to electrically couple the shingled stack of integrated circuit dies with traces of the substrate through the redistribution circuit.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “conjoined with” means “physically connected to” with or without an intervening structure or material. As used herein, “directly conjoined with” means “physically connected to” without an intervening structure or material.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
a first integrated circuit die conjoined with a second integrated circuit die in a stack of integrated circuit dies,
wherein the first integrated circuit die includes an end region that extends beyond an edge of the second integrated circuit die;
an interconnect structure that is conjoined with the end region and is electrically coupled to integrated circuitry of the first integrated circuit die;
a casing that encapsulates at least a portion of the interconnect structure, at least a portion of the first integrated circuit die, and at least a portion of the second integrated circuit die; and
an electrical trace that is conjoined with a surface of the casing, is disposed along a contour of the casing, and is electrically coupled to the interconnect structure.

2. The apparatus of claim 1, wherein the interconnect structure is a pillar structure.

3. The apparatus of claim 1, wherein the interconnect structure is a ball bond structure.

4. The apparatus of claim 1, wherein the electrical trace comprises:
an adhesion layer,
a core conductive layer, and
a capping layer.

5. The apparatus of claim 1, wherein the contour of the casing includes:
a first portion that is approximately parallel to lengthwise surfaces of the first integrated circuit die and the second integrated circuit die, and
a second portion that is angled relative to the first portion.

6. A semiconductor package, comprising:
a stack of integrated circuit dies arranged in a shingled fashion to form a stepped profile along an end region of the stack;
a casing that encapsulates the stack, comprising:
a first surface that is approximately planar; and
a second surface that is angled relative to the first surface and that is proximate the stepped profile;
a redistribution circuit directly conjoined with the casing, comprising:
a first portion that is disposed along the first surface; and
a second portion that is disposed along the second surface;
an array of external interconnect structures that conjoins with the first portion and that extends away from the casing; and
an array of internal interconnect structures that conjoins with the second portion and that extends into the casing to connect with the stack.

7. The semiconductor package of claim 6, further comprising:
a protective layer that is over the redistribution circuit.

8. The semiconductor package of claim 6, wherein the stack of integrated circuit dies comprises:
a first integrated circuit die including first memory integrated circuitry, and
a second integrated circuit die including second memory integrated circuitry,
wherein the first portion electrically couples the first memory integrated circuitry and the second memory integrated circuitry to form intra-package channels.

9. The semiconductor package of claim 8, wherein the stack of integrated circuit dies further comprises:
a third integrated circuit die between the first integrated circuit die and the second integrated circuit die.

10. The semiconductor package of claim 6, wherein the first portion comprises:
one or more pad structures.

11. The semiconductor package of claim 10, wherein the second portion includes a bus that electrically couples with the one or more pad structures.

12. The semiconductor package of claim 6, wherein the stack of integrated circuit dies comprises:
a first integrated circuit die including memory integrated circuitry, and
a second integrated circuit die including application specific integrated circuitry.

13. The semiconductor package of claim 12, wherein the array of internal interconnect structures comprises:
an interconnect structure that is mechanically coupled to the second integrated circuit die,
wherein the interconnect structure is configured to manage a thermal performance of the stack by conducting heat that is generated by the stack away from the stack.

14. The semiconductor package of claim 12, wherein the array of internal interconnect structures comprises:
an interconnect structure that is electrically coupled to the second integrated circuit die,
wherein the interconnect structure is configured to provide power to the stack through the second integrated circuit die.

15. An integrated assembly, comprising:
a printed circuit board; and
a stacked semiconductor package structure mounted to the printed circuit board, comprising:
a first substrate-less semiconductor package, comprising:
a first integrated circuit;
a first casing that encapsulates the first integrated circuit; and
a first interconnect structure that extends from the first integrated circuit to a first angled surface of the first casing;
a second substrate-less semiconductor package stacked with the first substrate-less semiconductor package, comprising:
a second integrated circuit; and
a second casing that encapsulates the second integrated circuit;
a second interconnect structure that extends from the second integrated circuit to a second angled surface of the second casing; and
a redistribution circuit including portions that are directly conjoined with the first casing and the second casing, comprising:
a first portion that is along the first angled surface and that conjoins with the first interconnect structure,
a second portion that is along the second angled surface and that conjoins with the second interconnect structure.

16. The integrated assembly of claim 15, wherein the first integrated circuit comprises a first stack of integrated circuit dies, comprising:
a first integrated circuit die including first memory integrated circuitry, and
wherein the second integrated circuit comprises a second stack of integrated circuit dies, comprising:
a second integrated circuit die including second memory integrated circuitry,
wherein the first portion and the second portion electrically couple the first memory integrated circuitry and the second memory integrated circuitry to form inter-package channels.

17. The integrated assembly of claim 15, wherein the second integrated circuit comprises a stack of integrated circuit dies, comprising:
a first integrated circuit die including memory integrated circuitry, and
a second integrated circuit die including interface integrated circuitry.

18. The integrated assembly of claim 17, wherein the interface integrated circuitry is directly coupled to external interconnect structures.

19. A method, comprising:
forming an integrated circuit on a temporary carrier;
forming a casing that surrounds the integrated circuit;
removing a portion of the casing to expose an interconnect structure that conjoins with the integrated circuit; and
forming a redistribution circuit directly on the casing that conjoins with the interconnect structure.

20. The method of claim 19, wherein forming the integrated circuit includes:
placing an integrated circuit die that includes the interconnect structure over the temporary carrier.

21. The method of claim 20, wherein placing the integrated circuit die is part of a die stacking operation that forms a stack of integrated circuit dies on the temporary carrier.

22. The method of claim 19, wherein forming the integrated circuit includes:
placing an integrated circuit die over the temporary carrier, and
forming the interconnect structure on the integrated circuit die.

23. The method of claim 22, wherein placing the integrated circuit die is part of a die stacking operation that forms a stack of integrated circuit dies on the temporary carrier.

24. The method of claim 19, wherein forming the casing includes:
forming the casing using a film-based molding operation.

25. The method of claim 19, wherein forming the redistribution circuit includes:
sputtering at least one conductive layer onto the casing through a mask above the casing,
wherein the mask patterns the redistribution circuit from the at least one conductive layer.

26. The method of claim 19, wherein forming the redistribution circuit includes:
sputtering at least one conductive layer onto the casing, and
using a lithography process to pattern the redistribution circuit from the at least one conductive layer.

27. The method of claim 19, wherein removing the portion of the casing includes:
removing the portion of the casing using a grinding tool with a beveled profile,
wherein removing the portion forms an angled, exposed surface of the interconnect structure.

28. The method of claim 19, wherein removing the portion of the casing includes:
removing the portion of the casing using a grinding tool that is oriented at an angle relative to the casing,
wherein removing the portion forms an angled, exposed surface of the interconnect structure.

29. The method of claim 19, wherein the portion of the casing is a first portion, and further including:
removing a second portion of the casing as part of defining edges of a semiconductor package that includes the integrated circuit, the casing, the interconnect structure, and the redistribution circuit.

30. The method of claim 19, wherein the interconnect structure is a first interconnect structure, and further including:
forming a protective layer over the redistribution circuit, and
forming a second interconnect structure over a pad of the redistribution circuit through an opening in the protective layer.

31. The method of claim 30, wherein forming the protective layer includes:
forming a solder mask, or
forming a passivation layer.

32. A method, comprising:
receiving a first semiconductor package having a redistribution circuit that is directly conjoined with a surface of a casing and that is electrically coupled to an integrated circuit through an array of interconnect structures that penetrates into the casing and connects to the integrated circuit;
testing the integrated circuit using the redistribution circuit; and
joining the first semiconductor package with a second semiconductor package to form a stacked semiconductor package structure.

33. The method of claim 32, wherein testing the integrated circuit includes:
testing the integrated circuit by probing pads of the redistribution circuit.

34. The method of claim 32, wherein testing the integrated circuit includes:
testing the integrated circuit by probing interconnect structures connected to the redistribution circuit.

35. The method of claim 32, further comprising:
mounting the stacked semiconductor package structure to a circuit board.
